(19) United States
(12) Patent Application Publication
(10) Pub. No.: US 2007/0082226 A1
(43) Pub. Date: Apr. 12, 2007

(54) Organic light emitting diode and display device employing the same

(75) Inventor: Chen-Ping Yu, Longtan Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/374,822

(22) Filed: Mar. 14, 2006

(30) Foreign Application Priority Data
Oct. 7, 2005 (TW) 94135178

(51) Int. Cl. H01L 51/54

(52) U.S. Cl. 428/690; 428/917; 428/212; 313/504; 313/506

(57) ABSTRACT

An organic light emitting diode comprises a cathode, an anode, an emitting layer disposed between the cathode and the anode, a hole injection layer disposed between the anode and the emitting layer, a hole transport layer disposed between the hole injection layer and the emitting layer, and a buffer layer disposed between the hole injection layer and the hole transport layer. The invention also provides a display apparatus including the organic light emitting diode.

### BACKGROUND OF THE INVENTION

1. Field of the Invention

The invention relates to an organic light emitting diode, and in particular to an organic light emitting diode with a buffer layer.

2. Description of the Related Art

Recently, development of photoelectron devices such as organic light emitting device, organic solar energy batteries or organic thin film transistors (OTFT) is industry focus such photoelectron device provide several advantages, such as direct conversion of light into electric power without pollution and noise.

In addition to solar energy batteries, organic thin film transistors can be formed on a plastic substrate to provide a flexible display due to ductility and elasticity superior to that of silicon. Conventional TFT-LCDs are formed by a process similar to the conventional semiconductor process. OTFT, however, is formed by process such as screen printing, ink-jet printing or contact printing. Polymers and amorphous molecules applied to the organic semiconductor materials of the OTFT can form the large-area semiconductor layer by spin-coating and ink-jet printing, substantially reducing the cost and processing temperature.

Generally, an organic light emitting device is composed of a light emitting layer sandwiched between a pair of electrodes. When applying an electric field to the electrodes, the cathode injects holes into the lighting emitting layer and the anode injects electrons into the light emitting layer. The electrons and holes recombine in the light emitting layer to form excitons. The excitons deliver energy to the emitting molecules in the light emitting layer, which is released in the form of light. A conventional organic light emitting device comprises a hole transport layer formed on the anode, an emitting layer formed on the hole transport layer, an electron transport layer formed on the emitting layer, and a cathode formed on the electron transport layer. In addition, a conventional organic light emitting device further comprises a hole injection layer disposed between the anode and the hole transport layer to improve hole injection efficiency, and an electron injection layer disposed between the cathode and the electron transport layer to improve electron injection efficiency, thus reducing the driving voltage and increasing the recombination probability of holes and electrons. The electron injection layer of the conventional organic light emitting device, however, is costly for mass production, and therefore it is desirable to reduce the material cost thereof.

### BRIEF SUMMARY OF THE INVENTION

An organic light emitting diode of the invention comprises at least a cathode and an anode, an emitting layer disposed between the cathode and the anode, a hole transport layer disposed between the hole injection layer and the emitting layer, and a buffer layer disposed between the hole injection layer and the hole transport layer.

Further provided is a display device, comprising the organic light emitting diode.

A detailed description is given in the following with reference to the accompanying drawing.

### BRIEF DESCRIPTION OF THE DRAWINGS

The invention can be more fully understood by reading the subsequent detailed description and examples with references made to the accompanying drawings, wherein:

FIG. 1 is a cross section of a conventional organic light emitting diode; and

FIG. 2 is a cross section of an organic light emitting diode according to the invention.

### DETAILED DESCRIPTION OF INVENTION

The invention provides an organic light emitting diode, as shown in FIG. 2, comprising a cathode 22 and an anode 11, an emitting layer 16 disposed between the cathode 22 and anode 11, a hole injection layer 120 disposed between the anode 11 and the emitting layer 16, a hole transport layer 140 disposed between the hole injection layer 120 and the emitting layer 16, and a buffer layer 130 disposed between the hole injection layer 120 and the hole transport layer 140.

The cathode 22 or the anode 11 is transparent, and the other may be metal such as Al, Ca, Ag, Ni, Cr, Ti, metal alloy such as Mg—Ag alloy, transparent metal oxide such as indium tin oxide (ITO), indium zinc oxide (IZO), cadmium tin oxide (CTO), metallized (AZO), zinc oxide (ZnO), indium nitride (InN), stannum dioxide (SnO₂) or combinations thereof. The cathode 22 and the anode 11 can be the same or different materialls.

The emitting layer 16 comprises a host material and a dopant, wherein the host material comprises ADN(9,10-bis(2-naphthalenyl)anthracene) and the dopant comprises DSA(distyrylarylene), and the volume ratio of the host material to the dopant is between 50:1 and 10:1. In addition, the thickness of the emitting layer 16 is between about 30 nm and 40 nm, preferably 30 nm. The hole injection layer 120 comprises organic material, such as starburst arylamine, and p-type impurity, wherein the starburst arylamine comprises IT-NANA, 2T-NANA or m-MTDATA, and the p-type impurity comprises TCNQ, F4-TCNQ or DDQ. The volume ratio of the starburst arylamine to the p-type impurity is between about 100:1 and 100:10, and the thickness thereof is between about 15 nm and 200 nm. The hole transport layer comprises tertiary arylamine such as NPB, HT2, TPD, DPFL-NPB, DPFL-TPD, DMFL-NPB, DPML-TPD, Spiro-NPB or Spiro-TAD, and the thickness thereof is substantially between 20 nm and 40 nm, preferably 20 nm.

The buffer layer 130 is formed between the hole injection layer 120 and the hole transport layer, and the thickness thereof is between about 15 nm and 200 nm, preferably 110 nm. The buffer layer 130 comprises starburst arylamine, tertiary arylamine and p-type impurities, wherein the starburst arylamine comprises IT-NANA, 2T-NANA or m-MTDATA, the tertiary arylamine comprises NPB, HT2, TPD, DPFL-NPB, DPFL-TPD, DMFL-NPB, DPML-TPD, Spiro-NPB or Spiro-TAD, and the p-type impurity comprises TCNQ, F4-TCNQ or DDQ. The volume ratio of the starburst arylamine to tertiary arylamine is between about 10:1 and 1:10, preferably 1:1, and the volume percentage of the p-type impurity in the buffer layer 130 is between about 1% and 10%. The thickness ratio of the buffer layer 130 to the hole injection layer 120 is between about 10:1 and 1:10. The electron transport layer is formed between the cathode 22 and the emitting layer 16 and the thickness thereof is between about 20 nm and 40 nm. The electron transport layer comprises Alq₃.

The organic light emitting diode of the invention further comprises an electron injection layer 20 disposed between the cathode 22 and the electron transport layer 18. The electron injection layer 20 comprises alkali metal halide, alkaline-earth metal halide, alkali metal oxide or metal carbonate, such as LiF, CsF, NaF, CaF₂, Li₂O, Cs₂O, Na₂O, Li₂CO₃, Na₂CO₃. The disclosed chemical formula is

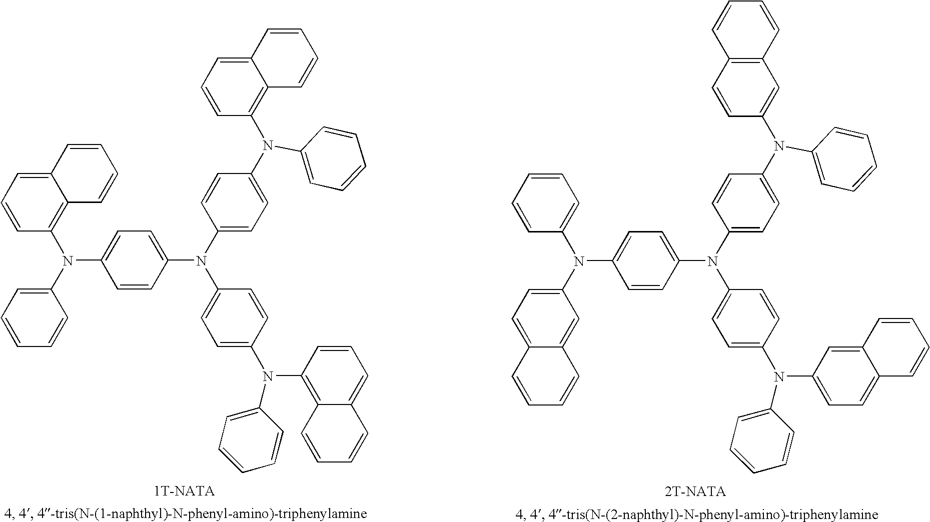

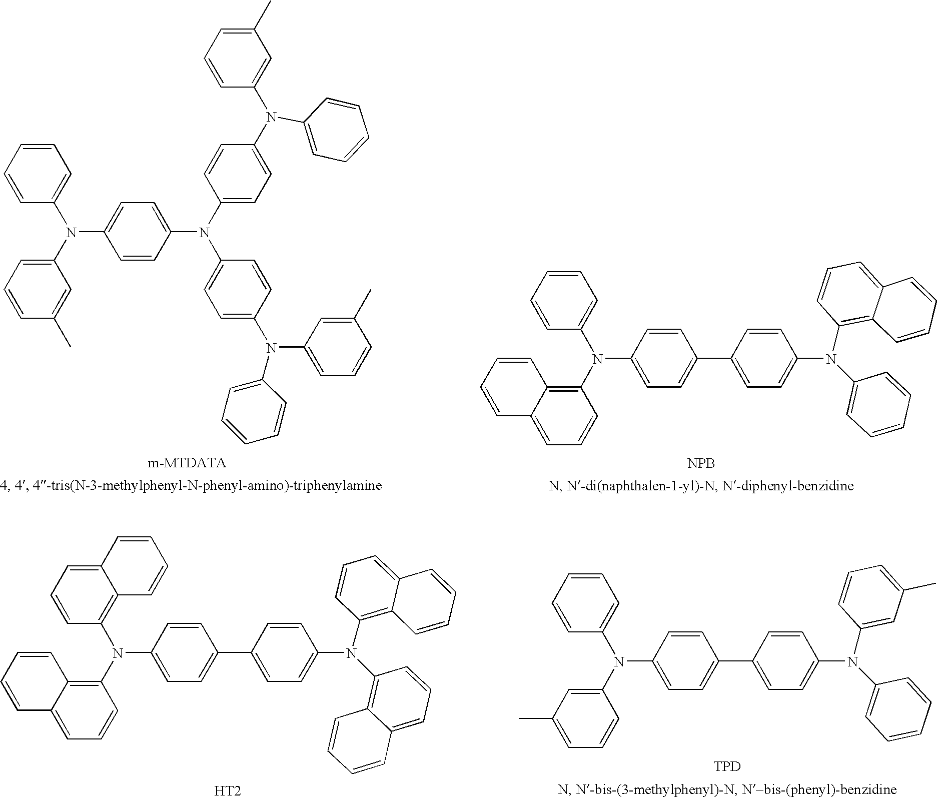

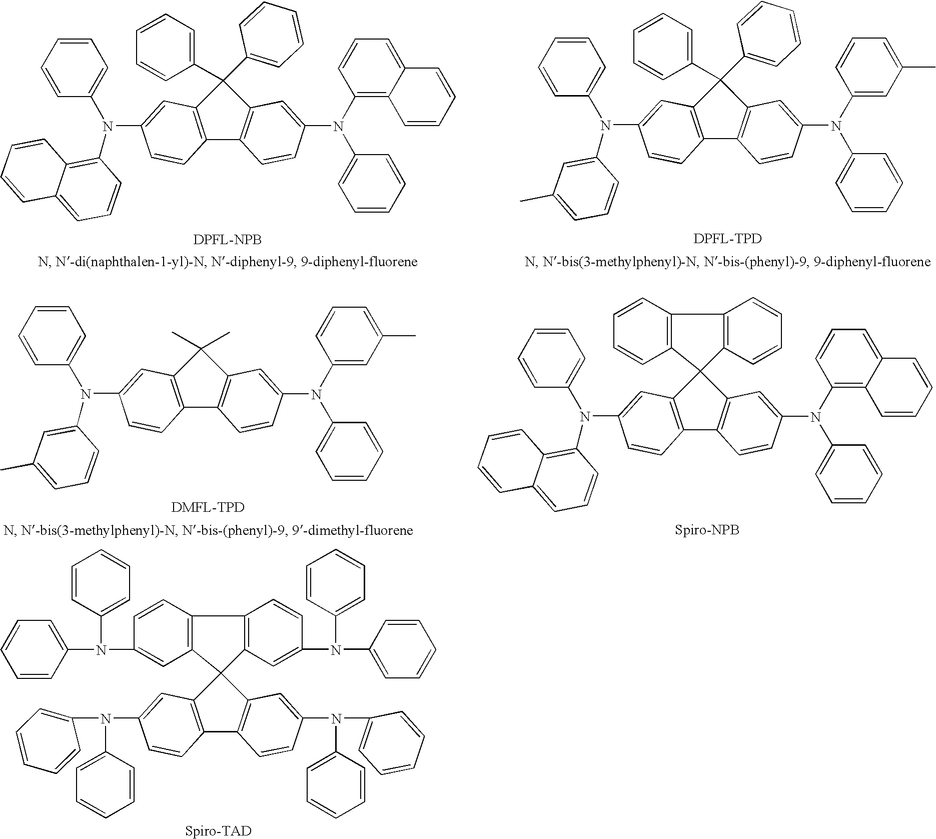

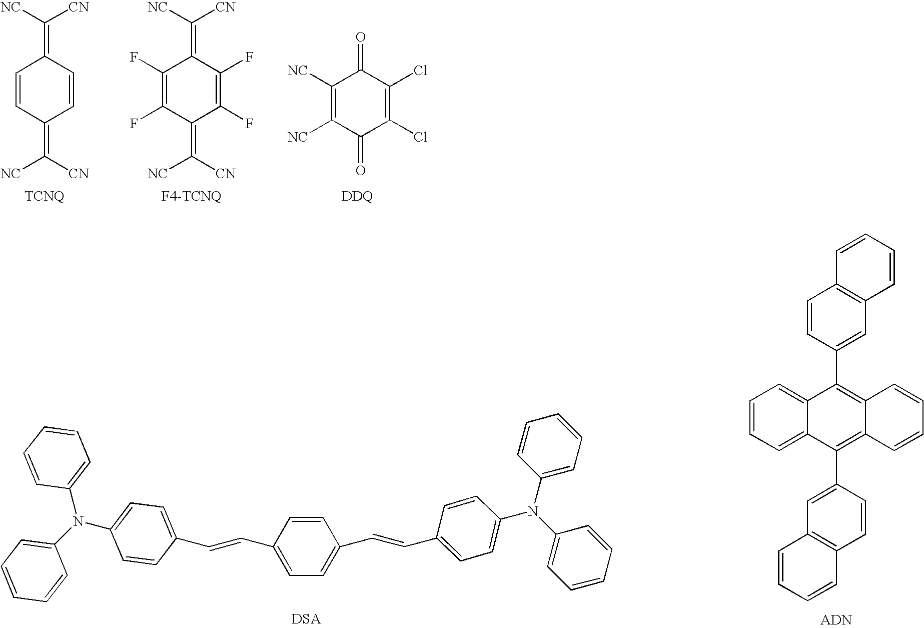

### COMPARATIVE EXAMPLE

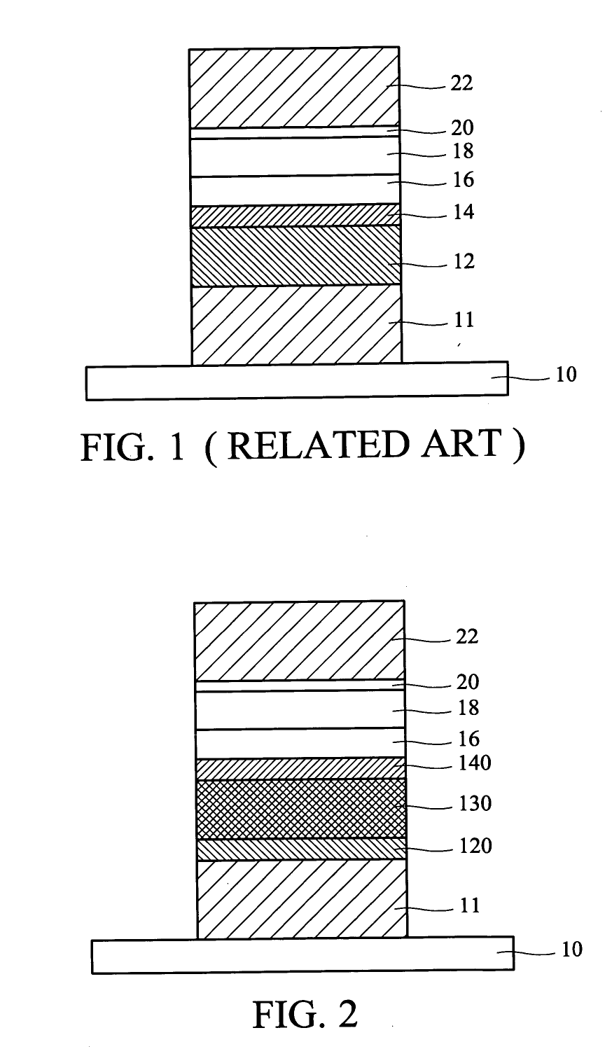

As shown in FIG. 1, a glass substrate 10 with ITO film formed thereon was provided, and then cleaned by cleaning agent, propyl alcohol, ethanol or ultrasonic, and dried by argon and treated with ozone. 2T-NATA and F4-TCNQ was deposited on the glass substrate 10 under 10⁻⁴ Pa by co-evaporation deposition to a thickness of about 150 nm as a hole injection layer 12, with volume ratio thereof about 100:6. NPB (4,4′-bis[N-(naphthyl)-N-phenyl-amino]biphenyl) was deposited on the hole injection layer 12 by evaporation deposition to a thickness of about 20 nm as a hole transport layer 14. ADN (9,10-bis(2-naphthalenyl)anthracene)and DSA(distyrylarylene) were deposited on the hole transport layer 14 by co-evaporation deposition to a thickness of about 30 nm as a light emitting layer 16, with volume ratio thereof about 100:2.5. Alq₃ (tris(8-hydroxyquinoline)aluminum(III)) was deposited on the light emitting layer 16 by evaporation deposition to a thickness of about 30 nm as an electron transport layer 18. LiF was deposited on the electron transport layer 18 to a thickness of about 1 nm as electron injection layer 20. Al was then deposited on the electron injection layer as a cathode, and packaged to be a light emitting diode.

### Example 1-2

As shown in FIG. 2, a glass substrate 10 with ITO film 11 formed thereon was provided, and cleaned by cleaning agent, propyl alcohol, ethanol or ultrasonic, and dried by argon and treated with ozone. In example 1 and example 2 of the invention, 2T:NATA and F4-TCNQ were deposited on the glass substrate 10 under 10 Pa by co-evaporation deposition to a thickness of about 20 nm and 40 nm respectively as a hole injection layer 120, with volume ratio thereof about 100:6. 2T-NATA, NPB (4,4′-bis[N-(naphthyl)-N-phenyl-amino]biphenyl) and F4-TCNQ were deposited on the hole injection layer 120 by co-evaporation deposition to a thickness of about 130 nm and 110 nm respectively as a buffer layer 130, with volume ratio of 2T-NATA to NPB about 1:1. NPB (4,4′-bis[N-(naphthyl)-N-phenyl-amino]biphenyl) was deposited on the buffer layer 130 to a thickness of 20 nm as a hole transport layer 140. ADN(9,10-bis(2-naphthalenyl)anthracene) and DSA(distyrylarylene) were deposited on the hole transport layer 140 by co-evaporation deposition to a thickness of about 30 nm as a light emitting layer 160, with volume ratio thereof about 100:2.5. Alq₃ (tris(8-hydroxyquinoline)aluminum(III)) was deposited on the light emitting layer 16 by evaporation deposition to a thickness of about 30 nm as a electron transport layer 18. LiF was deposited on the electron transport layer 18 to a thickness of about 1 nm as electron injection layer 20. Al was then deposited on the electron injection layer as a cathode, and packaged to be a light emitting diode.

Table 1 shows variation in operational voltage and brightness with thickness of the buffer layer 130 in examples 1-2 and the comparative example, wherein x is the thickness of the hole injection layer and y is the thickness of the buffer layer. Operational voltage of the organic light emitting diode in the comparative example is about 6.2V. As the buffer was formed between the hole injection layer and the hole transport layer, the operational voltage decreased to 5.7V. When buffer layer thickness increased to 130 nm and hole injection layer thickness decreased to 20 nm, the operational voltage remained about 5.7V and brightness did not change with the variation in thickness. Accordingly, the buffer layer reduced the amount of hole injection layer and operational voltage thereof.

TABLE 1

| | thickness(nm) | | operational | |
|---|---|---|---|---|
| example | X | Y | voltage(V) | brightness(cd/m²) |
| 1 | 20 | 130 | 5.7 | 1000 |
| 2 | 40 | 110 | 5.7 | 1000 |
| comparative | 150 | 0 | 6.2 | 1000 |

Table 2 shows variation in operational voltage and brightness with doping amount of p-type impurity (F4-TCNQ) in the buffer layer. The difference between the examples 3-5 and example 1 is the doping amount of p-type impurity. According to Table 2, the operational voltage of the organic light emitting diode obviously decreased with the doping amount of the p-type impurity increasing. As the doping amount of the p-type impurity increased over 10% the operational voltage remained the same. Accordingly, the preferred doping amount of p-type impurity is between 1% and 10%.

TABLE 2

| | doping ratio(%) | operational | |
|---|---|---|---|
| example | z | voltage(V) | brightness(cd/m²) |
| 3 | 2 | 6.0 | 1000 |
| 1 | 6 | 5.7 | 1000 |
| 4 | 12 | 5.4 | 1000 |
| 5 | 16 | 5.4 | 1000 |

Finally, while the invention has been described by way of example and in terms of preferred embodiment, it is to be understood that the invention is not limited thereto. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. An organic light emitting diode, comprising
a cathode and an anode;
an emitting layer disposed between the cathode and the anode;
a hole injection layer disposed between the anode and the emitting layer;
a hole transport layer disposed between the hole injection layer and the emitting layer; and
a buffer layer disposed between the hole injection layer and the hole transport layer.

2. The organic light emitting diode as claimed in claim 1, wherein the hole injection layer comprises starburst arylamine and p-type impurity.

3. The organic light emitting diode as claimed in claim 2, wherein the starburst arylamine comprises IT-NANA, 2T-NANA, or m-MTDATA.

4. The organic light emitting diode as claimed in claim 2, wherein the p-type impurity comprises TCNQ, F4-TCNQ, or DDQ.

5. The organic light emitting diode as claimed in claim 1, wherein the hole transport layer is tertiary arylamine.

6. The organic light emitting diode as claimed in claim 5, wherein the tertiary arylamine comprises NPB, HT2, TPD, DPFL-NPB, DPFL-TPD, DMFL-NPB, DPML-TPD, Spiro-NPB, or Spiro-TAD.

7. The organic light emitting diode as claimed in claim 1, wherein the buffer layer comprises the material of the hole injection layer and the material of the hole transport layer.

8. The organic light emitting diode as claimed in claim 7, wherein the hole injection layer comprises starburst arylamine, and the buffer layer further comprises a hole transport material and starburst arylamine.

9. The organic light emitting diode as claimed in claim 8, wherein the hole transport material comprises tertiary arylamine.

10. The organic light emitting diode as claimed in claim 1, wherein the buffer layer comprises starburst arylamine, tertiary arylamine, and p-type impurity.

11. The organic light emitting diode as claimed in claim 10, wherein the starburst arylamine comprises 1T-NANA, 2T-NANA, or m-MTDATA.

12. The organic light emitting diode as claimed in claim 10, wherein the p-type impurity comprises TCNQ, F4-TCNQ, or DDQ.

13. The organic light emitting diode as claimed in claim 10, wherein the tertiary arylamine comprises NPB, HT2, TPD, DPFL-NPB, DPFL-TPD, DMFL-NPB, DPML-TPD, Spiro-NPB, or Spiro-TAD.

14. The organic light emitting diode as claimed in claim 10, wherein the volume ratio of the starburst arylamine to the tertiary arylamine is between about 1:10 and about 10:1.

15. The organic light emitting diode as claimed in claim 10, wherein the volume ratio of the starburst arylamine to the tertiary arylamine is about 1:1.

16. The organic light emitting diode as claimed in claim 10, wherein the volume percentage of the p-type impurity in the buffer layer is between about 1% and about 10%.

17. The organic light emitting diode as claimed in claim 1, wherein the thickness ratio of the buffer layer to the hole injection layer is between about 10:1 and about 1:10.

18. The organic light emitting diode as claimed in claim 1, wherein the thickness of the hole injection layer is between about 15 nm and about 200 nm.

19. The organic light emitting diode as claimed in claim 1, wherein the thickness of the buffer layer is between about 15 nm and about 200 nm.

20. The organic light emitting diode as claimed in claim 1, wherein at least one of the cathode and the anode comprises a transparent electrode.

21. The organic light emitting diode as claimed in claim 1, wherein at lease one of the cathode and the anode comprises metal, alloy, transparent metal oxide, or a combination thereof.

22. The organic light emitting diode as claimed in claim 1, wherein the cathode and the anode are made of substantially the same material.

23. The organic light emitting diode as claimed in claim 1, wherein the cathode and the anode are made of different materials.

24. The organic light emitting diode as claimed in claim 1, wherein the emitting layer comprises fluorescent or phosphorescent materials.

25. The organic light emitting diode as claimed in claim 1, further comprising an electron transport layer disposed between the cathode and the emitting layer.

26. The organic light emitting diode as claimed in claim 22, further comprising an electron injection layer disposed between the electron transport layer and the cathode.

27. A display device, comprising
an organic light emitting diode of claim 1; and
a driving circuit, coupled to the organic light emitting diode, for driving the organic light emitting diode.

28. The display device as claimed in claim 27, wherein the driving circuit comprises a thin film transistor.
